(19) United States
(12) Patent Application Publication
(10) Pub. No.: US 2010/0027607 A1
(43) Pub. Date: Feb. 4, 2010

(54) APPARATUS FOR TIME-DOMAIN PRE-EMPHASIS AND TIME-DOMAIN EQUALIZATION AND ASSOCIATED METHODS

(76) Inventors: Tad Kwasniewski, Ottawa (CA); Shoujun Wang, Nepean (CA)

Correspondence Address: LAW OFFICES OF MAXIMILIAN R. PETERSON, P.O. BOX 93005, AUSTIN, TX, 78709-3005, US

(21) Appl. No.: 12/236,496

(22) Filed: Sep. 23, 2008

Related U.S. Application Data
(60) Provisional application No. 61/060,370, filed on Jun. 10, 2008.

(51) Int. Cl. H04L 27/00; H04L 25/03; H03H 7/30; H04L 7/00; H04L 27/06

(52) U.S. Cl. 375/232; 375/296; 375/259; 375/340; 375/371

(57) ABSTRACT

An integrated circuit (IC) includes a transmitter. The transmitter includes a pre-emphasis circuit. The pre-emphasis circuit pre-distorts an input signal by moving in time a sampling point of the input signal. The input signal is thus pre-distorted before transmission to a communication channel. The IC may optionally include a receiver. The receiver includes an equalization circuit. The equalization circuit equalizes a signal received from a communication channel by moving in time a sampling point of the signal received from the communication channel.

### CROSS-REFERENCE TO RELATED APPLICATIONS

This application claims priority to, and incorporates by reference, U.S. Provisional Patent Application Ser. No. 61/060,370, filed on Jun. 10, 2008, attorney docket number ALTR073P1.

### TECHNICAL FIELD

The disclosed concepts relate generally to improving digital communication and, more particularly, to time-domain pre-emphasis and equalization apparatus and associated methods.

### BACKGROUND

Digital communication has proliferated modern electronics. With increasing amounts of data, demand for faster communication and more bandwidth has also increased. For example, video and audio, even using compression and de-compression, when used on a relatively large scale, can result in the communication of large amounts of data. The data consume relatively large communication bandwidth in communication systems.

Any digital communication system uses a communication channel between the transmitter and the receiver. Channels typically have imperfections, which give rise to noise and interference. Furthermore, noise and interference may result from the operation of other electronic devices, natural phenomena, etc.

### SUMMARY

In one exemplary embodiment, an integrated circuit (IC) includes a transmitter. The transmitter includes a pre-emphasis circuit that pre-distorts an input signal by moving in time a sampling point of the input signal, such that the input signal is pre-distorted before transmission to a communication channel. In another exemplary embodiment, an IC includes a receiver. The receiver includes an equalization circuit that equalizes a signal received from a communication channel by moving in time a sampling point of the signal received from the communication channel.

In a third exemplary embodiment, a method of communicating via a communication channel includes pre-emphasizing a signal by advancing or retarding a sampling point of the signal to generate a pre-emphasized signal, and transmitting the pre-emphasized signal to the communication channel. According to yet another exemplary embodiment, a method of communicating via a communication channel includes receiving a signal from the communication channel, and equalizing the signal by advancing or retarding a sampling point of the signal received from the communication channel.

### BRIEF DESCRIPTION OF THE DRAWINGS

The appended drawings illustrate only exemplary embodiments and therefore should not be considered as limiting its scope. Persons of ordinary skill in the art who have the benefit of this disclosure appreciate that the disclosed concepts lend themselves to other equally effective embodiments. In the drawings, the same numeral designators used in more than one drawing denote the same, similar, or equivalent functionality, components, or blocks.

FIG. 1 illustrates a simplified conceptual block diagram of a communication system according to exemplary embodiments.

FIG. 2 depicts a simplified conceptual block diagram of an integrated circuit (IC) according to illustrative embodiments.

FIG. 3 shows a simplified conceptual block diagram of a programmable logic device (PLD) according to exemplary embodiments.

FIG. 4 depicts a simplified conceptual block diagram of a transmitter according to an exemplary embodiment.

FIG. 5 shows a simplified conceptual block diagram of a receiver according to an exemplary embodiment.

FIG. 6 illustrates a simplified conceptual block diagram of a transmitter according to an exemplary embodiment.

FIG. 7 depicts a simplified conceptual block diagram of a receiver according to an exemplary embodiment.

FIG. 8 shows a simplified conceptual block diagram of a receiver according to another exemplary embodiment.

### DETAILED DESCRIPTION

The disclosed concepts relate generally to improving digital communication in electronic apparatus. More specifically, the disclosed concepts provide apparatus and methods for transmitters with pre-emphasis and receivers with equalization for use in electronic devices, such as integrated circuits (ICs). The disclosed concepts provide transmitters and receivers with reduced complexity and with lower power consumption than conventional approaches.

As persons of ordinary skill in the art who have the benefit of the description of the disclosed concepts understand, distortion and interference can occur in communication systems. Specifically, inter-symbol interference (ISI) can corrupt data symbols and lead to erroneous data communication. ISI can result when a data symbol does not return to zero before the arrival of the next data symbol. To combat this problem, one may use pre-emphasis at the transmitter, and equalization at the receiver.

Pre-emphasis and equalization are channel-dependent processes. To pre-emphasize for a given channel according to the disclosed concepts, one adjusts or controls the sampling point of one or more symbols. One then transmits the pre-distorted or pre-emphasized signal to the receiver via the communication channel. The pre-emphasis or pre-distortion results in the data symbol's return to zero before the arrival of the next symbol. Thus, pre-emphasis eliminates or tends to eliminate ISI.

During transmission to the receiver, the communication channel may further distort the signal. Thus, the signal arriving at the receiver includes distortion from both pre-emphasis at the transmitter, and distortion or loss from the imperfect communication channel.

To account for both types of distortion, the receiver applies equalization to the received channel. Typically, one does so by subtracting a value from the received signal. In typical equalization scheme, the subtracted value constitutes a fixed percentage of the peak value of the signal (the receiver employs a circuit that determines the peak value of the signal). To perform equalization, the receiver moves an edge of the data signal in time. In other words, it moves forward or back in time an edge of the signal or, put differently, advances or retards in time an edge of the signal. The disclosed concepts use this edge-timing technique in various embodiments (e.g., synchronous and blind), as described below in detail.

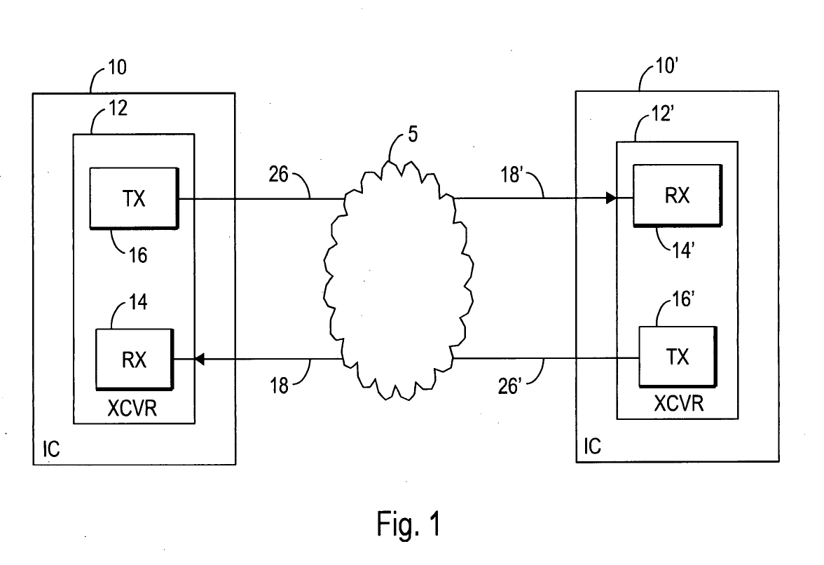

FIG. 1 illustrates a simplified conceptual block diagram of a communication system according to exemplary embodiments. The system includes IC 10 and IC 10′ (the prime notations merely serves to differentiate the labels for similar blocks). IC 10 includes transceiver 12, which includes transmitter 16 and receiver 14.

Transmitter 16 communicates with (i.e., transmits signals to) communication channel 5 via link 26 (e.g., bus, fiber, conductor, wire, etc.). Receiver 14 communicates with (i.e., receives signals from) communication channel 5 via link 18 (e.g., bus, fiber, conductor, wire, etc.).

Similarly, IC 10′ includes transceiver 12′, which includes transmitter 16′ and receiver 14′. Transmitter 16′ communicates with (i.e., transmits signals to) communication channel 5 via link 26′ (e.g., bus, fiber, conductor, wire, etc.). Receiver 14′ communicates with (i.e., receives signals from) communication channel 5 via link 18′ (e.g., bus, fiber, conductor, wire, etc.).

Thus, communication channel 5 provides a pathway for transmitter 16 of IC 10 to communicate with, and provide data to, receiver 14′ of IC 10′. Similarly, communication channel 5 serves as a pathway for transmitter 16′ of IC 10′ to communicate with, and provide signals to, receiver 14 of IC 10.

Note that, as persons of ordinary skill in the art who have the benefit of the description of the disclosed concepts understand, rather than including transceiver 12, IC 10 may include a transmitter, rather than transceiver 12 (i.e., it might lack receiver 14). Similarly, as persons of ordinary skill in the art who have the benefit of the description of the disclosed concepts understand, IC 10′ may include a receiver, rather than transceiver 12′ (i.e., it might lack transmitter 16′). The choice of implementation depends on a variety of factors, such as the desired type and level of communication capability, etc., as persons of ordinary skill in the art who have the benefit of the description of the disclosed concepts understand.

Note further that, without loss of generality, one may apply the disclosed concepts to discrete circuitry, rather than ICs, as persons of ordinary skill in the art who have the benefit of the description of the disclosed concepts understand. Thus, transceiver 12 (or transmitter 16 and/or receiver 14) may exist in discrete form, as desired. Similarly, transceiver 12′ (or transmitter 16′ and/or receiver 14′) may exist in discrete form, as desired.

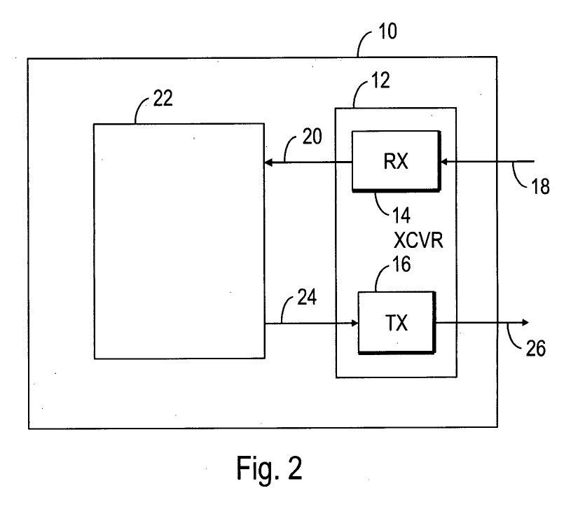

FIG. 2 depicts a more detailed conceptual block diagram of an IC according to illustrative embodiments. IC 10 includes circuitry 22, which communicates with transceiver 12 (or alternatively, with transmitter 16 or receiver 14). Circuitry 22 generally represents any circuit within IC 10 that can provide data or information to transceiver 12 or receiver data and information from transceiver 12, as persons of ordinary skill in the art who have the benefit of the description of the disclosed concepts understand.

Without loss of generality, circuitry 22 may include buffers, logic circuits, such as counters, gates, registers, flip-flops, input/output (I/O) circuits, etc. In addition, or instead, circuitry 22 may include blocks of circuitry that provide a given function, such as memories, processors, communication circuits, controllers, and the like, as desired, and as persons of ordinary skill in the art who have the benefit of the description of the disclosed concepts understand. Furthermore, circuitry 22 might provide a pathway to circuits or devices outside IC 10 so that such circuits or devices may communicate with transceiver 12 (or transmitter 16 or receiver 14), as desired.

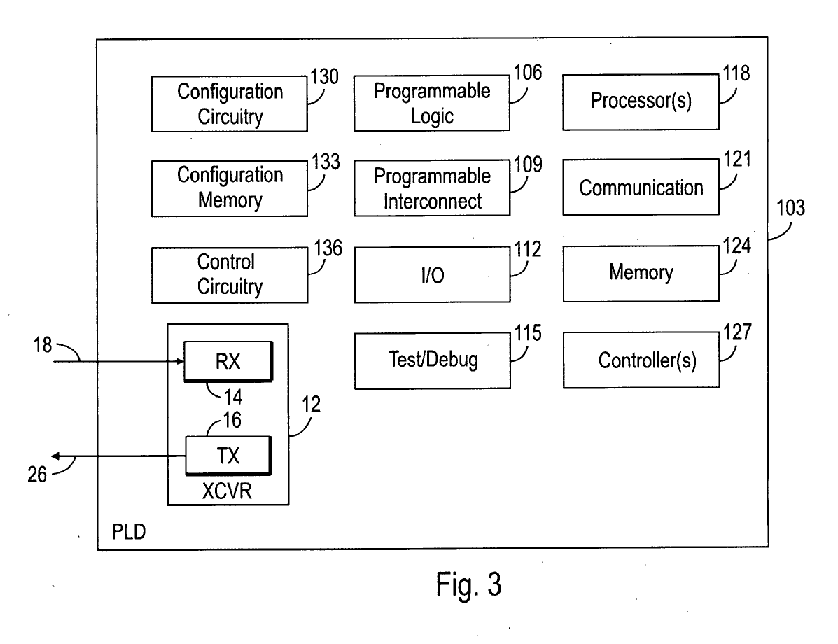

An example of an IC that may incorporate the disclosed concepts is a PLD. FIG. 3 shows a simplified conceptual block diagram of a PLD according to exemplary embodiments. PLD 103 includes configuration circuitry 130, configuration memory (CRAM) 133, control circuitry 136, programmable logic 106, programmable interconnect 109, and I/O circuitry 112. In addition, PLD 103 may include test/debug circuitry 115, one or more processors 118, one or more communication circuitry 121, one or more memories 124, one or more controllers 127, as desired.

Note that FIG. 3 shows a simplified block diagram of PLD 103. Thus, PLD 103 may include other blocks and circuitry, as persons of ordinary skill in the art understand. Examples of such circuitry include clock generation and distribution circuits, redundancy circuits, and the like. Furthermore, PLD 103 may include, analog circuitry, other digital circuitry, and/or mixed-signal circuitry, as desired. One may the design methodology and disclosed concepts to various resources, blocks, or circuits of PLD 103, as desired. Furthermore, one may apply the disclosed methodology and concepts to other PLD architectures, including any desired blocks, regions, or circuits, as persons of ordinary skill in the art who have the benefit of the description of the disclosed concepts understand.

Programmable logic 106 includes blocks of configurable or programmable logic circuitry, such as look-up tables (LUTs), product-term logic, multiplexers (MUXs), logic gates, registers, memory, and the like. Programmable interconnect 109 couples to programmable logic 106 and provides configurable interconnects (coupling mechanisms) between various blocks within programmable logic 106 and other circuitry within or outside PLD 103.

Control circuitry 136 controls various operations within PLD 103. Under the supervision of control circuitry 136, PLD configuration circuitry 130 uses configuration data (which it obtains from an external source, such as a storage device, a host, etc.) to program or configure the functionality of PLD 103. Configuration data typically store information in CRAM 133. The contents of CRAM 133 determine the functionality of various blocks of PLD 103, such as programmable logic 106 and programmable interconnect 109, as persons of ordinary skill in the art who have the benefit of this disclosure understand.

I/O circuitry 112 may constitute a wide variety of I/O devices or circuits, as persons of ordinary skill in the art who have the benefit of the description of the disclosed concepts understand. I/O circuitry 112 may couple to various parts of PLD 103, for example, programmable logic 106 and programmable interconnect 109. I/O circuitry 112 provides a mechanism and circuitry for various blocks within PLD 103 to communicate with external circuitry or devices.

Test/debug circuitry 115 facilitates the testing and troubleshooting of various blocks and circuits within PLD 103. Test/debug circuitry 115 may include a variety of blocks or circuits known to persons of ordinary skill in the art who have the benefit of the description of the disclosed concepts. For example, test/debug circuitry 115 may include circuits for performing tests after PLD 103 powers up or resets, as desired. Test/debug circuitry 115 may also include coding and parity circuits, as desired.

PLD 103 may include one or more processors 118. Processor 118 may couple to other blocks and circuits within PLD 103. Processor 118 may receive data and information from circuits within or external to PLD 103 and process the information in a wide variety of ways, as persons skilled in the art with the benefit of the description of the disclosed concepts appreciate. One or more of processor(s) 118 may constitute a digital signal processor (DSP). DSPs allow performing a wide variety of signal processing tasks, such as compression, decompression, audio processing, video processing, filtering, and the like, as desired.

PLD 103 may also include one or more communication circuits 121. Communication circuit(s) 121 may facilitate data and information exchange between various circuits within PLD 103 and circuits external to PLD 103, as persons of ordinary skill in the art who have the benefit of this disclosure understand.

PLD 103 may further include one or more memories 124 and one or more controller(s) 127. Memory 124 allows the storage of various data and information (such as user-data, intermediate results, calculation results, etc.) within PLD 103. Memory 124 may have a granular or block form, as desired. Controller 127 allows interfacing to, and controlling the operation and various functions of circuitry outside the PLD. For example, controller 127 may constitute a memory controller that interfaces to and controls an external synchronous dynamic random access memory (SDRAM), as desired.

PLD 103 further includes transceiver 12, which includes transmitter 16 and receiver 14. Transmitter 16 communicates with (i.e., transmits signals to) communication channel 5 (not shown explicitly) via link 26 (e.g., bus, fiber, conductor, wire, etc.). Receiver 14 communicates with (i.e., receives signals from) communication channel 5 (not shown explicitly) via link 18 (e.g., bus, fiber, conductor, wire, etc.).

Note that, as persons of ordinary skill in the art who have the benefit of the description of the disclosed concepts understand, rather than including transceiver 12, PLD 103 may include a transmitter, rather than transceiver 12 (i.e., it might lack receiver 14). Similarly, as persons of ordinary skill in the art who have the benefit of the description of the disclosed concepts understand, PLD 103 may include a receiver, rather than transceiver 12 (i.e., it might lack transmitter 16). The choice of implementation depends on a variety of factors, such as the desired type and level of communication capability (e.g., bi-directional vs. uni-directional), etc., as persons of ordinary skill in the art who have the benefit of the description of the disclosed concepts understand.

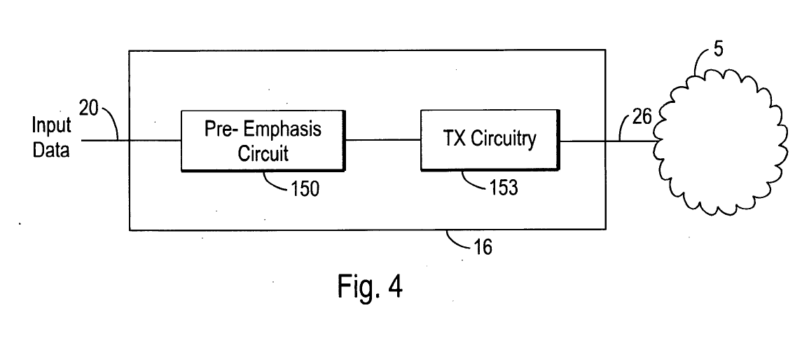

FIG. 4 depicts a simplified conceptual block diagram of a transmitter 16 according to an exemplary embodiment. Transmitter 16 includes pre-emphasis circuit 150 and transmitter circuitry 153. Pre-emphasis circuit 150 provides the pre-emphasis or pre-distortion functionality, described above in detail.

Transmitter circuitry 153 includes the circuitry of transmitter 16 (except for pre-emphasis circuit 150), which accepts pre-distorted or pre-emphasized data or information from pre-emphasis circuit 150, and transmits the data or information to channel 5. Transmitter circuitry 153 may have a variety of configurations and circuitry that fall within the knowledge and level of skill of persons of ordinary skill in the art who have the benefit of the description of the disclosed concepts. Examples of such circuits include CMOS, CML, or H-tree circuits that may provide various types of signals to channel 5.

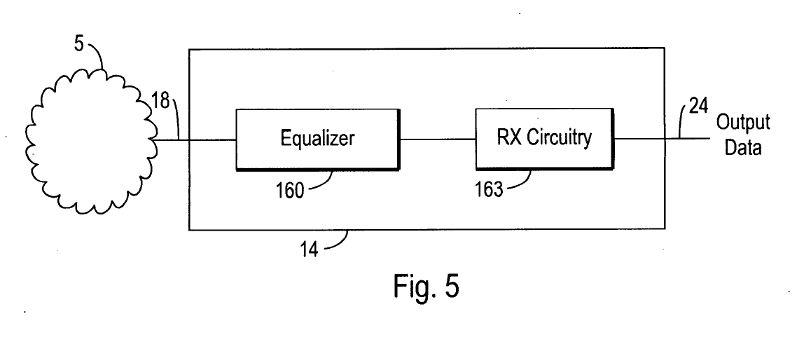

FIG. 5 shows a simplified conceptual block diagram of a receiver 14 according to an exemplary embodiment. Receiver 14 includes equalization circuit 160 and receiver circuitry 163. Equalization circuit 160 provides equalization for the pre-distortion or pre-emphasis added by the transmitter (see above for details) and, optionally, equalization for losses or distortion in channel 5, as desired and as described above in detail.

Receiver circuitry 163 includes the circuitry of receiver 14 (except for equalization circuit 160), which accepts equalized data or information from equalization circuit 160, and processes the data or information in order to provide them to follow-on circuitry (e.g., circuitry 22 in FIG. 2). Receiver circuitry 163 may have a variety of configurations and circuitry that fall within the knowledge and level of skill of persons of ordinary skill in the art who have the benefit of the description of the disclosed concepts. Examples of such circuits include CMOS, CML, or H-tree circuits.

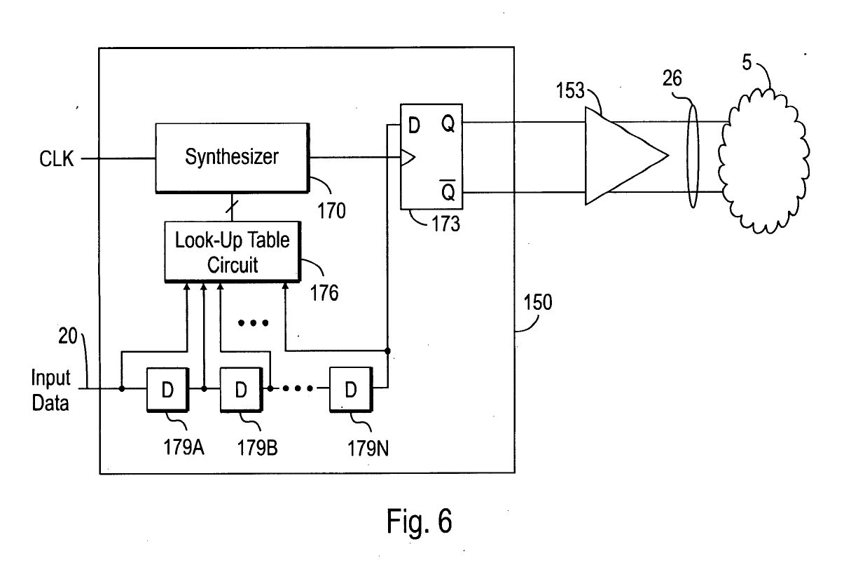

FIG. 6 illustrates a simplified conceptual block diagram of a transmitter 16 according to an exemplary embodiment that communicates via a communication channel. More specifically, the circuit arrangement in FIG. 6 shows more details of pre-emphasis circuit 150 (see FIG. 4) according to an exemplary embodiment.

Pre-emphasis circuit 150 includes a digital synthesizer 170, flip-flop 173, look-up table circuit 176, and a set of delay circuits 179A-179N. Digital synthesizer 170 receives a clock signal, CLK, and in response to the clock signal and a set of signals (described below in detail) received from look-up table circuit 176, generates a clock signal for flip-flop 173.

Furthermore, in response to receiving the signal from look-up table circuit 176 at its phase control input, digital synthesizer 170 causes the edge of the received signal to move in time, as described above, to accomplish equalization. Digital synthesizer 170 does so by using feedback in a loop that includes digital synthesizer 170, flip-flop 173, delay circuits 179A-179N, and look-up table circuit 176. Note that digital synthesizer 170 may use a variety of architectures and circuitry that fall within the knowledge and level of skill of persons of ordinary skill in the art who have the benefit of the description of the disclosed concepts.

Delay circuits 179A-179N couple in a cascade or chain fashion. The first delay circuit, i.e., delay circuit 179A, receives the input data via link 20, and provides a delayed version of it to the second delay circuit 179B, and so on, to the last delay circuit, i.e., delay circuit 179N. The number of delay circuits 179A-179N (i.e., the value of N, a positive integer), determines the level of resolution of the edge-timing operation. In other words, the higher the value of N, the smaller the minimum time period by which pre-emphasis circuit 150 can move the edge of the input data, and vice-versa. The choice of the value of N depends on the design and performance specifications for a particular use or implementation, as persons of ordinary skill in the art who have the benefit of the description of the disclosed concepts understand.

One may use a variety of circuitry or blocks to implement delay circuits 179A-179N, as persons of ordinary skill in the art who have the benefit of the description of the disclosed concepts understand. Without the loss of generality, examples of such circuitry include flip-flops and shift registers.

Look-up table circuit 176 receives the input data as well as the output signal of each of delay circuits 179A-179N. The input data and the output signal of each of delay circuits 179A-179N act as address signals for look-up table circuit 176. Depending on the values of the address signals, look-up table circuit 176 retrieves a pre-stored value, and provides that value to digital synthesizer 170. As noted, digital synthesizer 170 uses the value received from look-up table circuit 176 as a digital phase control value.

The amount of pre-emphasis or pre-distortion depends on the previous symbol or bit. Once one knows the attributes and properties of communication channel 5, one may store in look-up table circuit 176 appropriate values (i.e., phase values for digital synthesizer 170 to use), as persons of ordinary skill in the art who have the benefit of the description of the disclosed concepts understand. Using those values, pre-emphasis circuit 150 pre-emphasizes or pre-distorts each succeeding bit or symbol.

In response to the clock signal (i.e., output of digital synthesizer 170), flip-flop 173 samples the output of delay circuit 179N (i.e., a delayed version of the input data). Note that the output of flip-flop 173 includes pre-emphasis or pre-distortion, as described above. Flip-flop 173 provides its output signals (both true and complement, i.e., a differential signal) to transmitter circuitry 153 for processing and transmission to communication channel 5.

As persons of ordinary skill in the art who have the benefit of the description of the disclosed concepts understand, one may use single-ended rather than differential signals in the circuit arrangement of FIG. 6, as desired. As one way of doing so, one may use the true (or complement) output of flip-flop 173, rather than using both outputs. One would further modify transmitter circuitry 153 to accommodate single-ended signals. Those modifications fall within the knowledge and level of skill of persons of ordinary skill in the art who have the benefit of the description of the disclosed concepts.

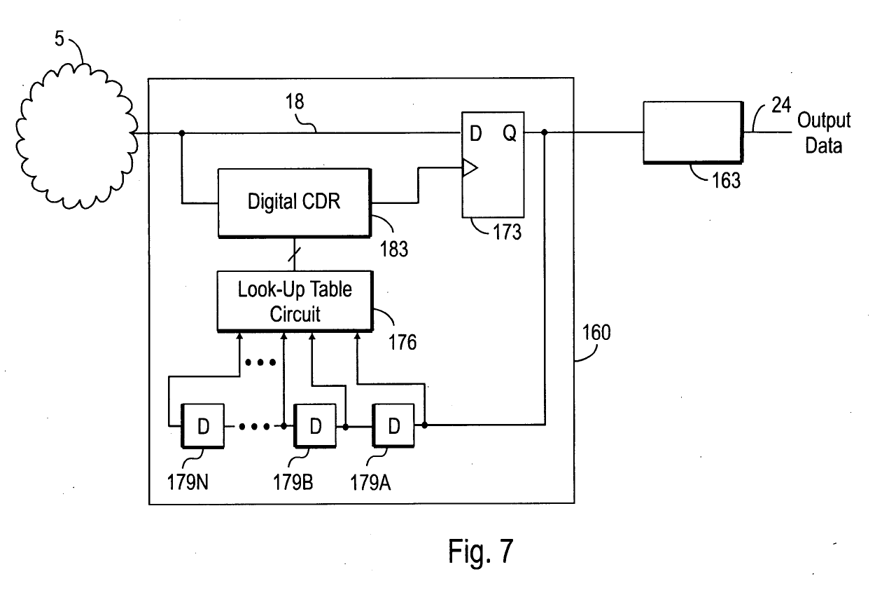

FIG. 7 depicts a simplified conceptual block diagram of a receiver 14 according to an exemplary embodiment that communicates via a communication channel. More specifically, the circuit arrangement in FIG. 7 shows more details of equalization circuit 160 (see FIG. 5) according to an exemplary embodiment.

Equalization circuit 160 includes flip-flop 173, digital clock data recovery (CDR) circuit 183, look-up table circuit 176, and a set of delay circuits 179A-179N. CDR circuit 183 accepts the received data or information from communication channel 5. At its output, CDR circuit 183 provides a clock signal to flip-flop 173. In response to the clock signal, flip-flop 173 samples the data or information received from communication channel 5. At its output, flip-flop 173 provides the sampled data or information to receiver circuitry 163 for further processing and communication to follow-on circuitry (e.g., circuitry 22 in FIG. 2) via link 24.

Equalization circuit 160 operates in cooperation with pre-emphasis circuit 150. Put another way, equalization circuit 160 receives (via communication channel 5) data or information that has been pre-emphasize or pre-distorted by pre-emphasis circuit 150. By applying equalization to the pre-emphasized or pre-distorted signal, equalization circuit 160 compensates for ISI or channel distortion/loss, or both, as desired, and as described above in detail.

As noted above, pre-emphasis circuit 150 employs an edge-timing operation. In a sense, equalization circuit 160 performs a complementary edge-timing operation to compensate for ISI or channel distortion/loss, or both. To do so, equalization circuit 160 uses feedback in a loop that includes CDR circuit 183, flip-flop 173, delay circuits 179A-179N, and look-up table circuit 176.

More specifically, using feedback, CDR circuit 183 adjusts or moves in time the sampling point (i.e., the phase of the sampling or clock signal) until it achieves an optimum or appropriate sampling point to accomplish equalization. Put another way, by examining past bits or symbols, equalization circuit 160 uses CDR circuit 183 in a feedback loop to apply digital correction to the data or symbol sampling point. The presence of feedback causes CDR 183 to lock onto the incoming data from channel 5. Note that CDR circuit 183 may use a variety of architectures and circuitry that fall within the knowledge and level of skill of persons of ordinary skill in the art who have the benefit of the description of the disclosed concepts.

Delay circuits 179A-179N couple in a cascade or chain fashion. The first delay circuit, i.e., delay circuit 179A, receives the input data via link 20, and provides a delayed version of it to the second delay circuit 179B, and so on, to the last delay circuit, i.e., delay circuit 179N. The number of delay circuits 179A-179N (i.e., the value of N, a positive integer), determines the level of resolution of the edge-timing operation. In other words, the higher the value of N, the smaller the minimum time period by which equalization circuit 160 can move the edge of the data signal, and vice-versa. The choice of the value of N depends on the design and performance specifications for a particular use or implementation, as persons of ordinary skill in the art who have the benefit of the description of the disclosed concepts understand.

One may use a variety of circuitry or blocks to implement delay circuits 179A-179N, as persons of ordinary skill in the art who have the benefit of the description of the disclosed concepts understand. Without the loss of generality, examples of such circuitry include flip-flops and shift registers.

Look-up table circuit 176 receives the output signal of flip-flop 173 as well as the output signal of each of delay circuits 179A-179N. The output signal of flip-flop 173 and the output signal of each of delay circuits 179A-179N act as address signals for look-up table circuit 176. Depending on the values of the address signals, look-up table circuit 176 retrieves a pre-stored value, and provides that value to CDR circuit 183. As noted, CDR 180 uses the value received from look-up table circuit 176 as a feedback signal to accomplish proper clock reconstruction and facilitate optimum or appropriate sampling of the input signal.

In response to the clock signal (i.e., output of CDR circuit 183, flip-flop 173 samples the signal received from communication channel 5. Note that the output of flip-flop 173 includes equalization, as described above. Flip-flop 173 provides its output signal to receiver circuitry 163 for processing and provision to follow-on circuitry (e.g., circuitry 22 in FIG. 2).

As persons of ordinary skill in the art who have the benefit of the description of the disclosed concepts understand, one may use differential rather than single-ended signals in the circuit arrangement of FIG. 7, as desired. As one way of doing so, one may use both the true and complement outputs of flip-flop 173, rather than using one of the outputs. One would further modify receiver circuitry 163 to accommodate differential signals. Those modifications fall within the knowledge and level of skill of persons of ordinary skill in the art who have the benefit of the description of the disclosed concepts.

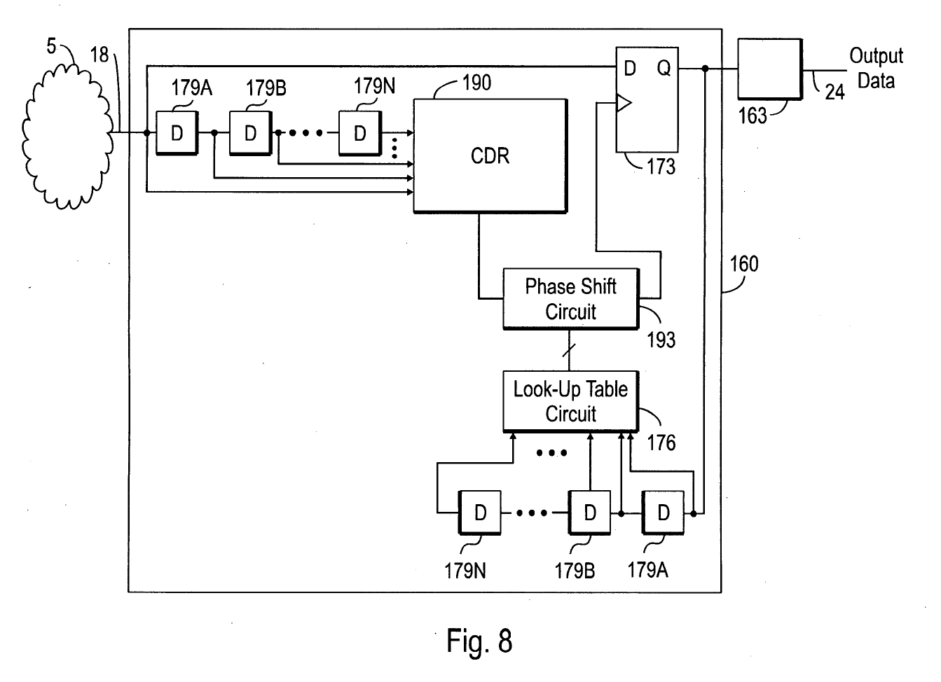

FIG. 8 shows a simplified conceptual block diagram of a receiver 14 according to another exemplary embodiment that communicates via a communication channel. More specifically, the circuit arrangement in FIG. 8 shows more details of equalization circuit 160 (see FIG. 5) according to an exemplary embodiment. Equalization circuit 160 includes a set of delay circuits 179A-179M, blind CDR circuit 190, flip-flop 173, phase shift circuit 193, look-up circuit 176, and a second set of delay circuits 179A-179N.

Conceptually, the circuit arrangement in FIG. 8 starts with an arbitrary waveform whose phase does not necessarily relate to the phase of the incoming data from channel 5. The equalization circuit uses that waveform to generate pulses with the period of the incoming data. The waveform has a frequency of M times larger than the incoming data. The equalization circuit takes M samples of the incoming data. Between two of the samples, an edge transition of the incoming data occurs. The transition point, plus half a period of the incoming data, represents the appropriate or optimum sampling point. Note that the equalization circuit in this embodiment operates in a “blind,” or not synchronous, manner.

Equalization circuit 160 operates in cooperation with pre-emphasis circuit 150. Put another way, equalization circuit 160 receives (via communication channel 5) data or information that has been pre-emphasize or pre-distorted by pre-emphasis circuit 150. By applying equalization to the pre-emphasized or pre-distorted signal, equalization circuit 160 compensates for ISI or channel distortion/loss, or both, as desired, and as described above in detail.

As noted above, pre-emphasis circuit 150 employs an edge-timing operation. In a sense, equalization circuit 160 performs a complementary edge-timing operation to compensate for ISI or channel distortion/loss, or both. To do so, equalization circuit 160 uses feedback in a loop that includes CDR circuit 190, phase shift circuit 193, flip-flop 173, delay circuits 179A-179N, and look-up table circuit 176. By using feedback, CDR circuit 190 finds an edge transition of the incoming data, which is used to locate the optimum or appropriate sampling point of the incoming data.

As noted, CDR circuit 190 constitutes a blind CDR. Put another way, CDR circuit 190 constitutes a discrete sample CDR that “blindly” takes samples, and does not use a phase detector. Note that CDR circuit 190 may use a variety of architectures and circuitry that fall within the knowledge and level of skill of persons of ordinary skill in the art who have the benefit of the description of the disclosed concepts.

Delay circuits 179A-179M couple in a cascade or chain fashion, and sample the incoming data. The first delay circuit, i.e., delay circuit 179A, receives the incoming data via link 20, and provides a delayed version of it to the second delay circuit 179B, and so on, to the last delay circuit, i.e., delay circuit 179M. The number of delay circuits 179A-179M (i.e., the value of M, a positive integer), determines the level of resolution of detecting the edge transition of the incoming data. In other words, the higher the value of M, the smaller the minimum time period by which equalization circuit 160 can detect an edge transition of the incoming data, and vice-versa. The choice of the value of M depends on the design and performance specifications for a particular use or implementation, as persons of ordinary skill in the art who have the benefit of the description of the disclosed concepts understand.

One may use a variety of circuitry or blocks to implement delay circuits 179A-179M, as persons of ordinary skill in the art who have the benefit of the description of the disclosed concepts understand. Without the loss of generality, examples of such circuitry include flip-flops and shift registers.

Delay circuits 179A-179M take M samples of the incoming data (i.e., data received from channel 5 via link 18), and provide the samples to blind CDR circuit 190 (effectively, a multi-sample phase detection circuit). Delay circuits 179A-179M have an equal delay value, TD. TD constitutes a sub-fraction of the baud rate of the incoming data (i.e., the data being received). CDR circuit 190 uses the M samples to detect an edge transition of the incoming data, and signals the transition at its output. Phase shift circuit 193 receives the output of CDR circuit 190, and shifts it by half a period of the incoming data. Phase shift circuit 193 provides the phase-shifted signal to flip-flop 173 as a clock signal.

Flip-flop 173 uses the clock signal to sample the incoming data (applied to its D input). Flip-flop 173 provides the sampled signal to delay circuits 179A-179N. Delay circuits 179A-179N couple in a cascade or chain fashion. The first delay circuit, i.e., delay circuit 179A, receives the output signal of flip-flop 173, and provides a delayed version of it to the second delay circuit 179B, and so on, to the last delay circuit, i.e., delay circuit 179N. The number of delay circuits 179A-179N (i.e., the value of N, a positive integer), determines the level of resolution of the edge-timing operation. In other words, the higher the value of N, the smaller the minimum time period by which equalization circuit 160 can move the edge of the data signal, and vice-versa. The choice of the value of N depends on the design and performance specifications for a particular use or implementation, as persons of ordinary skill in the art who have the benefit of the description of the disclosed concepts understand.

One may use a variety of circuitry or blocks to implement delay circuits 179A-179N, as persons of ordinary skill in the art who have the benefit of the description of the disclosed concepts understand. Without the loss of generality, examples of such circuitry include flip-flops and shift registers.

Look-up table circuit 176 receives the output signal of flip-flop 173 as well as the output signal of each of delay circuits 179A-179N. The output signal of flip-flop 173 and the output signal of each of delay circuits 179A-179N act as address signals for look-up table circuit 176. Depending on the values of the address signals, look-up table circuit 176 retrieves a pre-stored value, and provides that value to phase shift circuit 193. Phase shift circuit 193 uses the value received from look-up table circuit 176 as a feedback signal to accomplish proper or optimum sampling of the incoming data by flip-flop 173.

In response to the clock signal (i.e., output of CDR circuit 183, flip-flop 173 samples the signal received from communication channel 5. Note that the output of flip-flop 173 includes equalization, as described above. Flip-flop 173 provides its output signal to receiver circuitry 163 for processing and provision to follow-on circuitry (e.g., circuitry 22 in FIG. 2).

As persons of ordinary skill in the art who have the benefit of the description of the disclosed concepts understand, one may use differential rather than single-ended signals in the circuit arrangement of FIG. 8, as desired. As one way of doing so, one may use both the true and complement outputs of flip-flop 173, rather than using one of the outputs. One would further modify receiver circuitry 163 to accommodate differential signals. Those modifications fall within the knowledge and level of skill of persons of ordinary skill in the art who have the benefit of the description of the disclosed concepts.

As persons of ordinary skill in the art who have the benefit of the description of the disclosed concepts understand, one may apply the disclosed concepts effectively to various ICs, including general-purpose, custom, and other types of IC. One type of IC may include programmable or configurable logic circuitry, and may be known in the art by names other than PLDs, and as persons skilled in the art with the benefit of this disclosure understand. Examples of such circuitry include devices known as complex programmable logic device (CPLD), programmable gate array (PGA), and field programmable gate array (FPGA).

Referring to the figures, persons of ordinary skill in the art will note that the various blocks shown may depict mainly the conceptual functions and signal flow. The actual circuit implementation may or may not contain separately identifiable hardware for the various functional blocks and may or may not use the particular circuitry shown. For example, one may combine the functionality of various blocks into one circuit block, as desired. Furthermore, one may realize the functionality of a single block in several circuit blocks, as desired. The choice of circuit implementation depends on various factors, such as particular design and performance specifications for a given implementation, as persons of ordinary skill in the art who have the benefit of the description of this disclosure understand. Other modifications and alternative embodiments in addition to those described here will be apparent to persons of ordinary skill in the art who have the benefit of this disclosure. Accordingly, this description teaches those skilled in the art the manner of carrying out the disclosed concepts and are to be construed as illustrative only.

The forms and embodiments shown and described should be taken as the presently preferred or illustrative embodiments. Persons skilled in the art may make various changes in the shape, size and arrangement of parts without departing from the scope of the disclosure described in this document. For example, persons skilled in the art may substitute equivalent elements for the elements illustrated and described here. Moreover, persons skilled in the art who have the benefit of this disclosure may use certain features of the disclosed concepts independently of the use of other features, without departing from the scope of the disclosed concepts.

11. An integrated circuit (IC), comprising a transmitter, the transmitter including a pre-emphasis circuit that pre-distorts an input signal by moving in time a sampling point of the input signal, such that the input signal is pre-distorted before transmission to a communication channel.

2. The integrated circuit (IC) according to claim 1, wherein the pre-emphasis circuit comprises a digital synthesizer that receives a phase input derives from a plurality of samples of the input signal.

3. The integrated circuit (IC) according to claim 2, further comprising a plurality of delay circuits that provide the plurality of samples of the input signal.

4. The integrated circuit (IC) according to claim 2, wherein the digital synthesizer provides a clock signal used to sample the input signal.

5. The integrated circuit (IC) according to claim 4, further comprising a look-up table circuit that provides a digital phase control value to the digital synthesizer.

6. The integrated circuit (IC) according to claim 5, wherein the digital phase control value is derived from a plurality of samples of the input signal.

7. An integrated circuit (IC), comprising a receiver, the receiver including an equalization circuit that equalizes a signal received from a communication channel by moving in time a sampling point of the signal received from the communication channel.

8. The integrated circuit (IC) according to claim 7, wherein the equalization circuit comprises a digital clock data recovery (CDR) circuit coupled to accept the signal received from the communication channel.

9. The integrated circuit (IC) according to claim 8, wherein the clock data recovery (CDR) circuit provides a clock signal used to sample the signal received from the communication channel.

10. The integrated circuit (IC) according to claim 9, wherein the clock data recovery (CDR) circuit provides the clock signal based in part on previous values of the signal received from the communication channel.

11. The integrated circuit (IC) according to claim 9, wherein the equalization circuit further comprises:
a set of delay circuits that provide a set of delayed samples of the signal received from the communication channel; and
a look-up table circuit that uses the set of delayed samples of the signal received from the communication channel to provide a stored value to the clock data recovery (CDR) circuit.

12. The integrated circuit (IC) according to claim 7, wherein the equalization circuit further comprises a plurality of delay circuits that provide a set of delayed values of the signal received from the communication channel.

13. The integrated circuit (IC) according to claim 12, wherein the equalization circuit further comprises a blind clock data recovery (CDR) circuit that derives an output signal from the set of delayed values of the signal received from the communication channel.

14. The integrated circuit (IC) according to claim 13, wherein the equalization circuit further comprises a phase shift circuit that shifts the output signal of the blind clock data recovery (CDR) circuit to generate a clock signal used to sample the signal received from the communication channel.

15. The integrated circuit (IC) according to claim 14, wherein the phase shift circuit shifts the output signal of the blind clock data recovery (CDR) circuit based on the a value derived from a set of samples of the signal received from the communication channel.

16. A method of communicating via a communication channel, the method comprising:
pre-emphasizing a signal by advancing or retarding a sampling point of the signal to generate a pre-emphasized signal; and
transmitting the pre-emphasized signal to the communication channel.

17. The method according to claim 16, wherein advancing or retarding a sampling point of the signal further comprises using at least one past value of the signal to determine a sampling point of the signal.

18. The method according to claim 16, wherein a sampling point of the signal is selected so as to reduce inter-symbol interference (ISI).

19. The method according to claim 18, wherein the sampling point of the signal is selected to also compensate for loss in the communication channel.

20. The method according to claim 17, wherein using at least one past value of the signal to determine a sampling point of the signal comprises delaying the signal to generate the at least one past value of the signal.

21. The method according to claim 16, advancing or retarding a sampling point of the signal to generate a pre-emphasized signal comprises using feedback based on at least one past value of the signal.

22. A method of communicating via a communication channel, the method comprising:
receiving a signal from the communication channel; and
equalizing the signal by advancing or retarding a sampling point of the signal received from the communication channel.

23. The method according to claim 22, wherein advancing or retarding a sampling point of the signal received from the communication channel is performed synchronously.

24. The method according to claim 23, wherein advancing or retarding a sampling point of the signal received from the communication channel further comprises sampling the signal received from the communication channel based on at least one past sample of the signal received from the communication channel.

25. The method according to claim 23, wherein advancing or retarding a sampling point of the signal received from the communication channel further comprises using feedback to determine the sampling point of the signal received from the communication channel.

26. The method according to claim 22, wherein advancing or retarding a sampling point of the signal received from the communication channel is performed by obtaining a set of delayed values of the signal received from the communication channel to determine a transition edge of the signal received from the communication channel.

27. The method according to claim 26, wherein advancing or retarding a sampling point of the signal received from the communication channel further comprises sampling the signal received from the communication channel at a point in time defined by a sum of a time at which the transition edge occurs plus half a period of the signal received from the communication channel.

28. The method according to claim 26, wherein advancing or retarding a sampling point of the signal received from the communication channel is performed by using at least one past sample of the signal received from the communication channel.
